(19) United States
(12) Patent Application Publication
(10) Pub. No.: US 2008/0258292 A1
(43) Pub. Date: Oct. 23, 2008

(54) Macro-cell block and semiconductor device

(75) Inventor: Atsuhisa Fukuoka, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONCS CORPORATION, Kawasaki (JP)

(21) Appl. No.: 11/902,745

(22) Filed: Sep. 25, 2007

(30) Foreign Application Priority Data
Sep. 27, 2006 (JP) 262081/2006

(51) Int. Cl. H01L 23/52

(52) U.S. Cl. 257/691; 257/E23.141

(57) ABSTRACT

There have been cases where the wirings are not led out when a semiconductor chip comprising a conventional macro is mounted on a package substrate.

The macro-cell block is a macro-cell block formed polygonal having a plurality of sides and formed in a semiconductor chip, and is characterized by comprising a signal terminal portion, a power terminal portion, and a ground terminal portion, which are connected to the outside of a semiconductor chip, wherein the signal terminal portion is disposed along one side of the plurality of sides, and the power terminal portion is disposed along a side different from the side where the signal terminal portion is disposed, and the ground terminal portion is disposed along a side different from the side where the signal terminal portion is disposed.

### BACKGROUND OF THE INVENTION

1. Field of the Invention

The present invention relates to a semiconductor device, and in particular, it relates to a semiconductor device comprising a macro-cell block.

2. Description of the Related Art

In the conventional semiconductor integrated circuit, it is common that an inner circuit is designed in the center vicinity of the semiconductor chip and the chip peripheral portion is disposed with an input/output buffer and the like. FIG. 4 shows such a conventional semiconductor integrated circuit (semiconductor chip). In the semiconductor integrated circuit shown in FIG. 4, an input/output buffer area (hereinafter, referred to as I/O area) 44 for performing an input and output of the signals with the outside is disposed so as to surround an inner circuit 45. In this I/O area 44, a signal terminal portion 41 for performing an input/out of the signals with the outside, a power terminal portion 42, a grounding terminal portion 43, and the like are disposed.

On the other hand, in recent years, the number of integrated circuits has been on the increase in which circuits having a special function such as an A/D(Analog-to-Digital) converter, a D/A(Digital-to-Analog) converter, and PLL (Phase Locked Loop) are brought together as a macro cell block (hereinafter, referred to as macro) and are fitted into a circuit and developed. These macros often require, in addition to an I/O circuit dedicated to macro, dedicated power supply and GND independent from the power supply and the GND of the semiconductor chip mounted with such a macro. FIG. 5 is a view showing one example of the configuration of such a macro.

The macro 50 shown in FIG. 5 comprises a macro dedicated terminal portion such as a macro dedicated signal terminal portion (shown as MS) 51, a macro dedicated power terminal portion (shown as MV) 52, a macro dedicated GND terminal portion (shown as MG) 53. Further, the macro 50 comprises a main body portion 54 serving as a circuit for executing the functions of the macro 50. Inside the macro dedicated terminal portion, a macro dedicated signal terminal (macro dedicated signal pad), a macro dedicated power terminal (macro dedicated power pad), and a macro dedicated GND terminal (macro dedicated GND pad) are formed, respectively (not shown).

In the conventional macro shown in FIG. 5, the macro dedicated terminal portion is disposed according to the I/O area of a semiconductor chip 40 shown in FIG. 4. That is, the macro dedicated terminal portions 51, 52, and 53 are disposed to concentrate on one side of the macro 50. FIG. 6 shows a semiconductor chip comprising the macro 50 shown in FIG. 5 provided in the semiconductor chip 40 shown in FIG. 4. As shown in FIG. 6, when the conventional macro 50 is disposed on a chip, the macro dedicated terminal portions 51, 52, and 53 are disposed to line up on one side on the chip. When the macro 50 is disposed on the semiconductor chip 40 in this manner, the number of signal terminal portions 41 for the input output signals disposable in a chip peripheral I/O area 44 of the semiconductor chip 40 by the macro dedicated terminal portions 51, 52, and 53 is reduced. To solve the problem that the signal terminal portion 41 which can be disposed in this chip peripheral I/O area 44 is reduced, an area I/O technique is known, which is disclosed in Patent Document 1. This area I/O technique is a technique to provide the signal terminal portion 41 for input/output signals at an arbitrary position of the chip interior 45 and not limited to the chip peripheral I/O area 44 only. The disposition when this area I/O technique is used is shown in FIG. 7. As evident from FIG. 7, an inner area 45 of the semiconductor chip is provided with the signal terminal portion 41. The semiconductor chip 40 thus provided with the signal terminal portion is, for example, flip-chip mounted on a package substrate for BGA (Ball Gird Array) and the like, and is packaged.

However, when the semiconductor chip 40 as shown in FIG. 7 is mounted on the package substrate, it was often the case that the signal from the signal terminal (pad) of the signal terminal portion 41 formed in the inner area 45 is unable to be led outside of the package. FIGS. 8A and 8B are a schematic illustration to describe such a case.

As shown in FIGS. 8A and 8B, the signal terminal portion 41, the macro dedicated terminal portions 51, 52, and 53 on the semiconductor chip 40 are formed with terminals (pad) for connecting to the outside, respectively. Each terminal is electrically connected to a wiring inside a package substrate 830 through a bump electrode 833 and the like, and is led outside of the package by the wiring of the package substrate. Here, for example, in the line A-A′ shown in FIG. 7, a via 832 connected to the terminal inside the macro dedicated power terminal portion 52 penetrates a signal wiring layer SM connected to a terminal inside the signal terminal portion 41. Hence, there are often the cases where the signal from the signal terminal portion 41 formed by using the area I/O technique is unable to be led out till the outside of the package (see FIG. 8A). Further, in the line B-B′ shown in FIG. 7, a signal wiring layer from the terminal of the macro dedicated signal terminal portion 51 disposed in the I/O area 44 of the chip periphery exists. In this case also, there are often the cases where the signal from the terminal of the signal terminal portion 41 is unable to be led out (see FIG. 8B).

That is, in the semiconductor integrated circuit comprising the conventional macro-cell block, to compensate for the reduction in the number of signal terminal portions 41 by the macro dedicated signal terminal portion 51, the macro dedicated power terminal portion 52, and the macro dedicated GND terminal portion 53, the number of signal terminal portions 41 corresponding to the reduction has been secured by using the area I/O technique disclosed in the Patent Document 1. However, even the terminals of the signal terminal portions 41 led out by the area I/O technique were reduced in the degree of freedom for leading out the signal wiring layers to the outside of the package on the substrate such as the package. Hence, when the package is designed, it has been extremely difficult to optimize the wirings inside the package substrate. Further, in the conventional macro-cell block, since the macro dedicated signal terminal portion 51, the macro dedicated power terminal portion 52, and the macro dedicated GND terminal portion 53 were concentrated in one side, the size (vertical length in FIG. 5) of the macro-cell block became large according to the power supply, the GND, and the number of signal terminals which are required by the macro, thereby causing an obstacle to the miniaturization of the macro.

[Patent Document 1] Japanese Patent Laid-Open No. 2004-47516

### SUMMARY

When a semiconductor chip comprising the conventional macro is mounted on a package substrate, there are often the cases where wirings are not able to be let out.

According to one aspect of the present invention, a macro-cell block formed on a semiconductor chip comprises, a signal terminal portion, a power terminal portion, and a grounding terminal portion which are connected to the outside of said semiconductor chip, wherein said signal terminal portion is disposed along one side of said block, and wherein at least one of said power terminal portion or said grounding terminal portion is disposed along a side different from the side where said signal terminal is disposed.

Further, according to one aspect of the present invention, a macro-cell block disposed in a semiconductor chip, comprises, a signal terminal portion for macro-cell block formed in the peripheral portion of said semiconductor chip, and a power terminal portion for macro-cell block and a grounding terminal portion for macro-cell block formed nearer to an internal portion of said semiconductor chip than the said signal terminal portion for macro-cell block.

Further, a macro-cell block according to one aspect of the present invention a macro-cell block formed polygonal having a plurality of sides and formed in a semiconductor chip, comprises, a signal terminal portion disposed along one side of said planarity of sides, a power terminal portion disposed along a side different from the side disposed with said signal terminal portion, and a grounding terminal portion disposed along a side different from the side disposed with said signal terminal portion.

According to the macro-cell block according to one aspect of the present invention, when a semiconductor chip comprising the macro-cell block is mounted on a package substrate, the degree of freedom of the signal wiring at the side of the package substrate can be improved.

According to the present invention, a design of the package substrate mounted with the semiconductor chip comprising the macro can be made easy.

### BRIEF DESCRIPTION OF THE DRAWINGS

FIG. 1 is a block diagram of a macro-cell block according to a first embodiment of the present invention;

FIG. 2 is a block diagram in which the macro-cell block according to the first embodiment of the present invention shown in FIG. 1 is disposed on a semiconductor chip;

FIGS. 3A and 3B are block diagrams in which the semiconductor chip shown in FIG. 2 is mounted on a package substrate;

FIG. 4 is a view showing a conventional semiconductor chip;

FIG. 5 is a block diagram of a conventional macro-cell block;

FIG. 6 is a block diagram in which the macro-cell block shown in FIG. 5 is disposed in the semiconductor chip;

FIG. 7 is a block diagram when an area I/O technique is applied to the semiconductor chip shown in FIG. 6; and

FIGS. 8A and 8B are block diagrams in which the semiconductor chip shown in FIG. 7 is mounted on the package substrate.

### DETAILED DESCRIPTION OF THE PREFERRED EMBODIMENTS

### First Embodiment

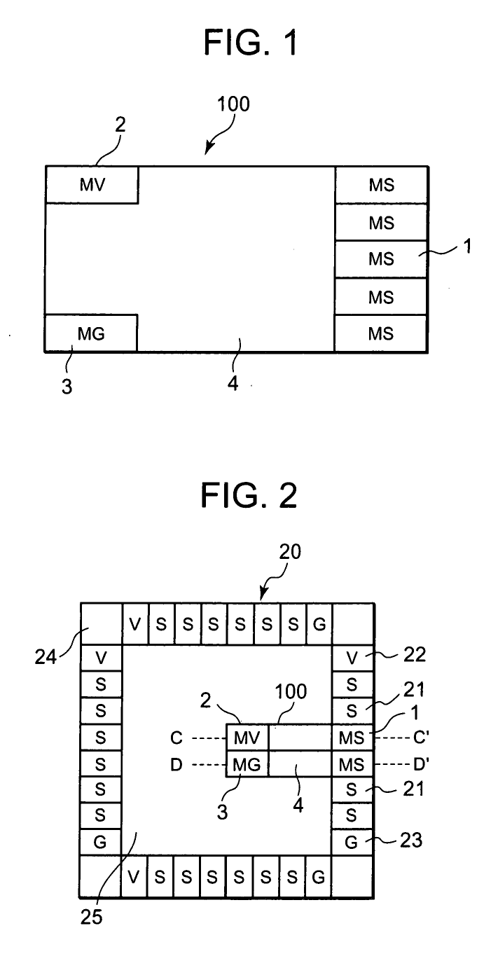

Hereinafter, embodiments of the present invention will be described with reference to the drawings. FIG. 1 is a view showing a macro-cell block (hereinafter, referred to as macro) 100 according to a first embodiment of the present invention. The macro referred to in the present embodiment is, for example, a core portion comprising predetermined functions such as CPU, RAM, ROM, and a multiplier. This macro is designed in advance as a circuit to realize the predetermined functions. While a description will be made below on the shape of the macro in the present embodiment as a quadrangle, the macro shape is not limited to the quadrangle, but may be a polygon having a convexity and a concavity. As shown in FIG. 1, the macro 100 of the present embodiment comprises macro dedicated signal terminal portion (shown as MS) 1, a macro dedicated power terminal portion (shown as MV) 2, a macro dedicated ground terminal portion (GND terminal portion shown as MG) 3, and a main body portion 4. The macro dedicated signal terminal portion 1 is plurally disposed on one side of the periphery (external peripheral portion) of the macro 100. Further, in the present embodiment, the macro dedicated power terminal portion 2 and the macro dedicated GND terminal portion 3 are disposed on a side opposing to the side where the macro dedicated signal terminals 1 are disposed. Further, the macro dedicated power terminal portion 2 and the macro dedicated GND terminal portion 3 receive a supply of the power/GND independent (separated) from the semiconductor chip. A portion other than the peripheral area disposed with these macro dedicated signal terminal portion 1, macro dedicated power terminal portion 2, and macro dedicated ground terminal portion 3 becomes a main body portion 4.

The main body portion 4 is a circuit portion to execute the functions of the macro 100. The macro dedicated signal terminal portion 1 is a portion to perform the input and output of the signals with the macro main body and the outside (the outside of the semiconductor chip mounted with the macro). The under layer (the under layer of the semiconductor chip and a transistor layer) of this macro dedicated signal terminal portion 1 is provided with the I/O circuit. Further, the macro dedicated signal terminal portion l is formed with a macro dedicated signal terminal (not shown) to perform the input and output of the signals with the outside. The macro signal terminal is, for example, a metallic pad formed on the surface of the semiconductor chip.

The macro dedicated power terminal portion 2 and the macro dedicated GND terminal portion 3 are portions giving a power supply and a ground potential to the macro 100. The under layers of the macro dedicated power terminal portion 2 and the macro dedicated GND terminal portion 3 (the under layers of the semiconductor chip and a transistor layer) can be, for example, configured to comprise a protection circuit such as an electrostatic discharge circuit (ESD). Further, the macro dedicated power terminal portion 2 and the macro dedicated GND terminal portion 3 are provided with a macro dedicated power terminal and a macro dedicated GND terminal for connecting a power supply potential and the ground potential. The macro dedicated power terminal and the macro dedicated GND terminal are formed as pads on the semiconductor chip.

According to the above description, the under layer of the macro dedicated signal terminal portion is formed with the I/O circuit, and the under layers of the macro dedicated power terminal portion 2 and the macro dedicated GND terminal portion 3 are formed with the protection circuits. However, the under layers of the macro dedicated signal terminal portion 1, the macro dedicated power terminal portion 2, and the macro dedicated GND terminal portion 3 are not necessarily required to be configured in such a manner. In the macro 100 of the present embodiment, even when the positions of the macro dedicated signal terminal position 1, the macro dedicated power terminal portion 2, and the macro dedicated GND terminal portion 3 are deviated from the position of the I/O circuit or the protection circuit, no particular problem is caused.

FIG. 2 is a view in which the macro 100 disposed as described above is mounted on a monolithic semiconductor device (hereinafter, referred to as semiconductor chip) 20. Incidentally, the macro 100 shown in FIG. 1 is assumed to be provided with five pieces of the macro dedicated signal terminal portions 1, whereas the macro shown in FIG. 2 is assumed to be provided with two pieces of the macro dedicated signal terminal portions 1. This is to make the drawing simple.

The semiconductor chip 20 comprises a chip inner area 25 and a chip peripheral I/O area 24. The chip inner area 25 is located in the center area of the semiconductor chip 20. The chip peripheral I/O area 24 is disposes so as to surround the periphery of the chip inner area 25.

The chip inner area 25 is provided on the semiconductor chip 20, and is an area where a basic cell, a logical gate or a macro is disposed. Further, the chip peripheral I/O area 24 is provided continuously across the entire periphery of semiconductor chip 20. Further, the chip peripheral I/O area 24 is a buffer area comprising an I/O buffer and a pad (including a signal pad, a power supply pad for I/O buffer, and a ground pad for I/O buffer).

In the present embodiment, the chip inner area 25 of the semiconductor chip 20 is disposed with the macro 100, and the chip peripheral I/O area 24 is disposed with input/output terminal portions such as a signal terminal portion (shown as S) 21, a power terminal portion (shown as V), 22, and a ground terminal portion (shown as G) 23. These terminal portions are formed with a signal terminal, a power terminal and a GND terminal, respectively (not shown). Further, the macro dedicated signal terminal portion 1 disposed on one side of the macro 100 described in FIG. 1 is disposed as a part of the chip peripheral I/O area 24 of the semiconductor chip 20 (see FIG. 2). Further, the macro dedicated power terminal portion 2 and the macro dedicated GND terminal portion 3 are provided in the inner area 25 closer to the chip center portion than the chip peripheral I/O area 24. By disposing the macro 100 which was described in this manner by using FIG. 1, a signal terminal portion 21 formed inside the chip by using the conventional area I/O technique can be disposed adjacent to the macro dedicated signal terminal portion 1.

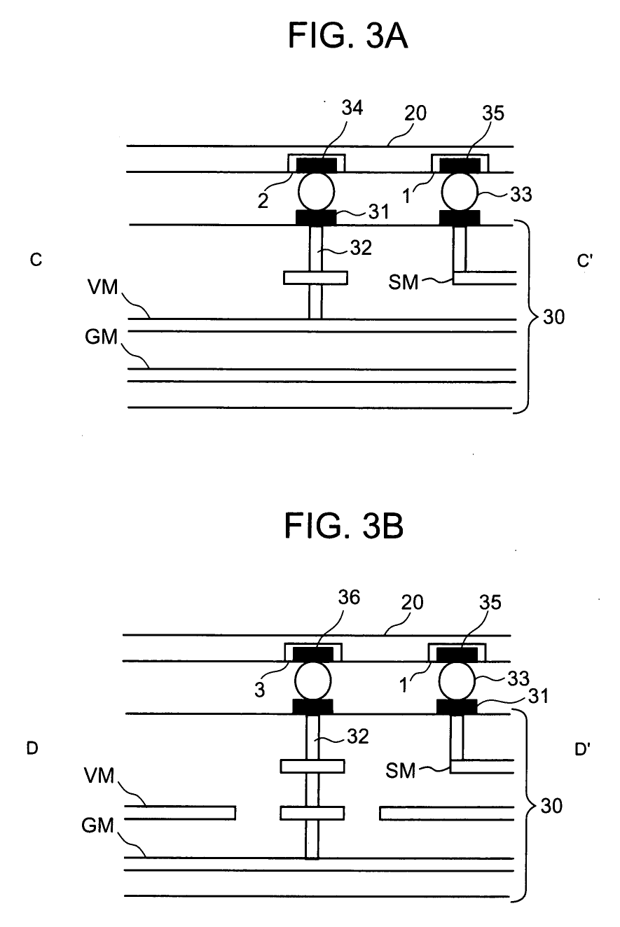

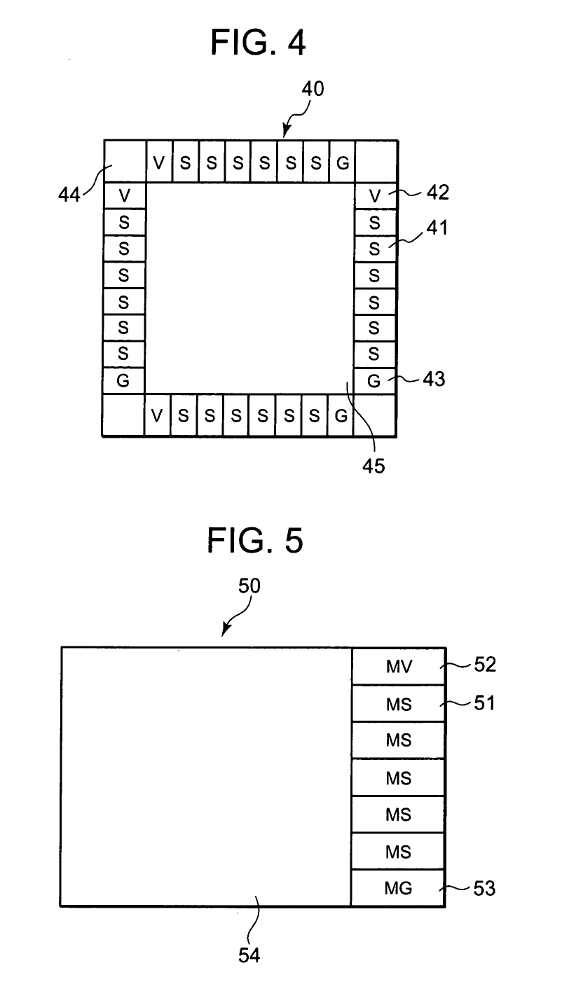

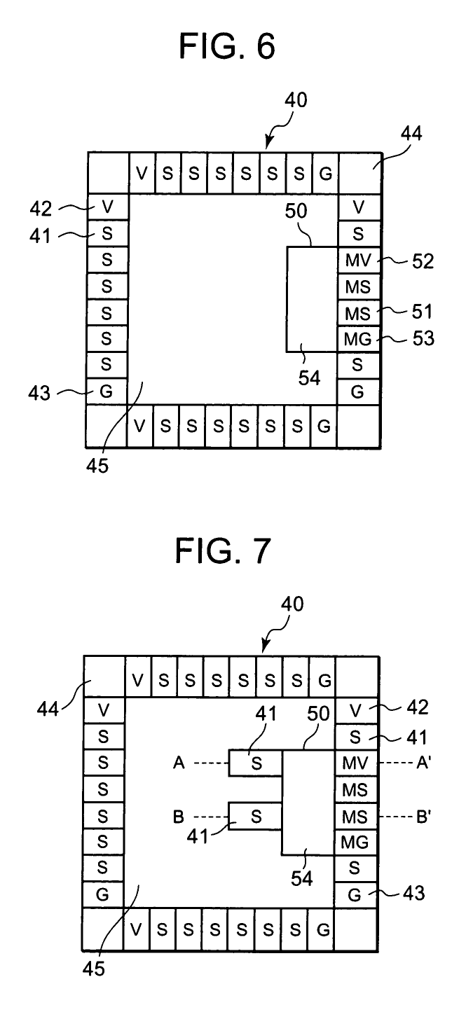

FIGS. 3A and 3B are shown a schematic illustration of a state in which the semiconductor chip 20 comprising the macro 100 is mounted on the package substrate 30. Here, the package substrate 30 comprises a package substrate terminal 31, a via 32, a signal wiring layer SM, a power supply layer VM, and a ground wiring layer GM. Here, the signal wiring layer SM is a wiring layer formed in a layer (chip mounting surface side) upper than the power terminal wiring VM and the ground wiring layer GM inside the package substrate. Further, on the package substrate terminal 31 of the package substrate 11, a bump electrode 34 such as a soldering ball is formed. Respective terminals 1 to 3, and 21 to 23 of the semiconductor chip 20 shown in FIG. 2 are, as shown in FIGS. 3A and 3B, formed with a macro dedicated power terminal 34, a macro dedicated signal terminal 35, and a macro dedicated GND terminal 36. These macro dedicated terminals are electrically connected to the package substrate 30 through the bump electrode 33. Further, the rear surface (surface opposite to the mounting surface of the semiconductor chip 20) of the package substrate 30 is, for example, formed with the external connecting terminal of a ball-shaped electrode (not shown). Further, the package substrate terminal 31 and each wiring layer (signal wiring layer SW, power supply layer VM, and ground wiring layer GM) are connected by a conductive post and the like formed in the inside of the via 32. The case where the package substrate 32 configured in this manner is mounted on the semiconductor chip 20 comprising the macro 30 will be described with reference to FIGS. 3A and 3B.

FIG. 3A is a cross-sectional view in case of mounting the semiconductor chip 20 comprising the macro 100 shown in FIG. 2 on the package substrate 30. Incidentally, FIG. 3A is a cross-sectional view along a line connecting the macro dedicated signal terminal portion 1 and the macro dedicated power terminal portion 2 formed in the macro (see line C-C′ in FIG. 2).

As shown in FIG. 3A, the macro dedicated signal terminal 35 of the macro dedicated signal terminal portion 1 is connected to the signal wiring layer SM through the bump electrode 33, the package substrate terminal 31, and the via 32. Through this signal wiring layer SM, the macro dedicated signal terminal 35 is connected to the external connecting terminal. Further, the micro dedicated power terminal 34 located inside the semiconductor chip 20 is also connected to the power supply layer VM through the bump electrode 33, an electrode terminal 31, and the via 32. Further, the power supply layer VM is connected to the external connecting terminal (not shown).

FIG. 3B is a cross-sectional view along a line connecting the macro dedicated signal terminal portion 1 and the macro dedicated GND terminal portion 3 in the semiconductor chip 20 (see line D-D′ in FIG. 2).

As shown in FIG. 3B, the macro dedicated signal terminal 35 is connected the signal wiring layer SM through the bump electrode 33, the electrode terminal 31, and the via 32. Through this signal wiring layer SM, the macro dedicated signal terminal 1 is connected to the external connecting terminal. Further, the macro dedicated GND terminal 36 located inside the semiconductor chip 20 is also connected to the ground wiring layer GM through the bump electrode 33, the electrode terminal 31 and the via 32. Further, the ground wiring layer GM is connected to the external connecting terminal (not shown).

Further, other signal terminals, which are not formed inside the macro dedicated signal terminal portion 1, are formed inside the signal terminal portion 21. The signal terminals formed inside the signal terminal portion 21 are connected to the signal wiring layer SM similarly to the macro dedicated signal terminal 35, and are connected to the external connecting terminal.

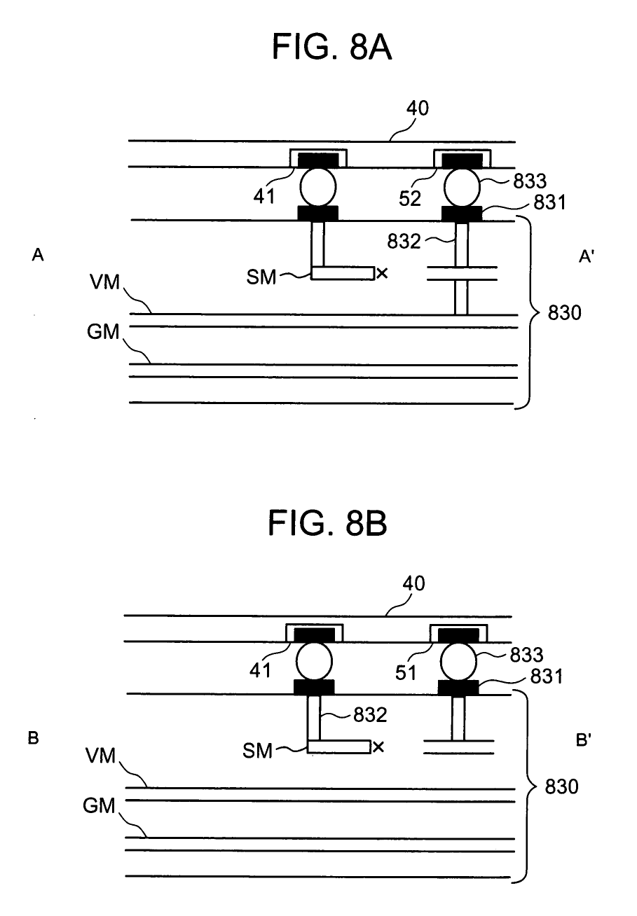

The package substrate and the like comprising a plurality of wiring layers form the power supply layer and installation wirings in a flat-plate like across the entire package to supply a power supply to various places inside the package. Hence, assuming that a macro such as the conventional one is used, a degree of freedom of the design for the signal wiring layer is deprived as described by using FIGS. 8A and 8B. In contrast to this, as shown in FIGS. 3A and 3B, by using the macro of the present embodiment, the via connected to the power supply layer VM and the ground wiring layer GM can be prevented from intersecting the signal wiring layer SM. Consequently, even when the power supply layer VM and the ground wiring layer GM are formed across the entire package substrate, the signal wiring layer SM is not affected by the via connected to the under layer. Further, the signal terminal portion formed in the area inside the chip by using the conventional area I/O technique can be disposed adjacent to the macro dedicated signal terminal portion 1, and therefore, a degree of freedom of the design of the signal wiring layer, which leads out the signal terminal of the signal terminal portion 21 to the external connecting terminal, is improved.

That is, in the present embodiment, the macro dedicated signal terminal portions 1 are disposed inside the macro 100 at one side, and the macro dedicated power terminal portion 2 and the macro dedicated GND terminal portion 3 are disposed at a side different from the macro dedicated signal terminal portions 1. By disposing the terminal portions in such a manner, the number of terminals disposable in the chip peripheral area 24 is increased, the signal terminal portions 21 of the semiconductor chip 20 can be disposed at both ends of the macro dedicated signal terminal portion 1. Consequently, the macro dedicated signal terminal portion 1 and the signal terminal portion 21 can be concentrated on the chip peripheral portion. As a result, in the package substrate comprising the plurality of wiring layers, the signal wiring layer can be freely led out to the external connecting terminal. Further, as described by using FIG. 5, though there have been the cases where the size of the conventional macro becomes large by the number of terminals, by using the macro of the present embodiment, as shown in FIG. 1, the vertical length of the macro 100 can be formed small.

Further, a design of the substrate of the package such as a flip-chip BGA mounting the semiconductor chip 20 using such a macro-cell block and a printed circuit board is made easy, and the increase in the wiring layers of the substrate or board can be inhibited.

Incidentally, in the present embodiment, one side disposed with the macro dedicated signal terminal portions 1 and one side disposed with the macro dedicated power supply layer 2 and the macro dedicated GND terminal portion 3 are formed so as to be mutually opposed. However, the external periphery of the macro 100 disposed with the macro dedicated signal terminal portions 1 may be separated from the side disposed with the macro dedicated power supply layer 2 and the macro dedicated GND terminal portion 3. For example, the macro dedicated GND terminal portion 3 in FIG. 1 can be also formed on the upper side portion shown in FIG. 1 adjacent to the macro dedicated power terminal portion 2.

While the description bas been made in detail based on the embodiment of the present invention, the invention can be variously modified unless the spirit of the present invention is deviated. For example, in the present embodiment, though a description has been made on the case where the semiconductor chip 20 is mounted on the package substrate, even when it is a printed circuit board mounted in a bare chip, the same effect as the present invention can be obtained.

Further, in the present embodiment, at least one of said power terminal portion or said grounding terminal portion is disposed along a side different from the side where the signal terminal portion is disposed, the same effect as the present invention can be obtained.

What is claimed is:

1. A macro-cell block formed on a semiconductor chip comprising:
a signal terminal portion, a power terminal portion, and a grounding terminal portion which are connected to the outside of said semiconductor chip,
wherein said signal terminal portion is disposed along one side of said block; and
wherein at least one of said power terminal portion or said grounding terminal portion is disposed along a side different from the side where said signal terminal is disposed.

2. The macro-cell block according to claim 1, wherein both of said power terminal portion and said grounding terminal portion are disposed along a side different from the side where said signal terminal is disposed.

3. The macro-cell block according to claim 1, wherein said macro-cell block formed polygonal having a plurality of sides and formed on a semiconductor chip.

4. The macro-cell block according to claim 1, characterized in that the side where said plurality of signal terminal portions are disposed is configured to be parallel with the side of the semiconductor chip including said macro-cell block.

5. A semiconductor chip comprising the macro-cell block according to claim 1.

6. The semiconductor chip according to claim 5, wherein said side disposed with said signal terminal portion is configured to be parallel with the side of the semiconductor chip including staid macro-cell block.

7. The semiconductor chip according to claim 5, wherein said macro-cell block is disposed so that said signal terminal portion is positioned at an I/O area prepared in the periphery of said semiconductor chip.

8. The semiconductor chip according to claim 5, wherein at least one of said power terminal portion or grounding terminal portion is nearer to the center portion of said semiconductor chip than said signal terminal portion.

9. A semiconductor device comprising a semiconductor chip including the macro-cell block according to claim 1 and a substrate mounting said semiconductor chip.

10. The semiconductor device according to claim 9, wherein said substrate comprises a plurality of wiring layers.

11. The semiconductor device according to claim 9, wherein said substrate comprises:
a signal wiring layer electrically connected to said signal terminal portion;
a power supply layer electrically connected to said power terminal portion; and
a ground wiring layer electrically connected to said grounding terminal portion,
wherein said signal wiring layer is closer in the direction vertical to the chip to said chip than said power supply layer and said ground wiring layer.

12. The semiconductor device according to claim 9, wherein said substrate comprises:
a signal wiring layer electrically connected to said signal terminal portion;
at least one of a power supply layer electrically connected to said power terminal portion or a ground wiring layer electrically connected to said grounding terminal portion,
wherein said signal wiring layer is closer in the direction vertical to the chip to said chip than said power supply layer and said ground wiring layer.

13. The semiconductor device according to claim 10, wherein said substrate comprises:
a signal wiring layer electrically connected to said signal terminal portion;
a power supply layer electrically connected to said power terminal portion; and
a ground wiring layer electrically connected to said grounding terminal portion,
wherein said signal wiring layer is closer in the direction vertical to the chip to said chip than said power supply layer and said ground wiring layer.

14. The semiconductor device according to claim 10, wherein said substrate comprises:
a signal wiring layer electrically connected to said signal terminal portion;
at least one of a power supply layer electrically connected to said power terminal portion or a ground wiring layer electrically connected to said grounding terminal portion,
wherein said signal wiring layer is closer in the direction vertical to the chip to said chip than said power supply layer and said ground wiring layer.

15. A macro-cell block disposed in a semiconductor chip, comprising:
a signal terminal portion for macro-cell block formed in the peripheral portion of said semiconductor chip; and
a power terminal portion for macro-cell block and a grounding terminal portion for macro-cell block formed nearer to an internal portion of said semiconductor chip than the said signal terminal portion for macro-cell block.

16. The macro-cell block according to claim 15, wherein said signal terminal portion for macro-cell block is disposed along a side of said chip where other signal terminal portions are formed adjacent to said signal terminal portion.

17. A macro-cell block formed polygonal having a plurality of sides and formed in a semiconductor chip, comprising:
a signal terminal portion disposed along one side of said planarity of sides;
a power terminal portion disposed along a side different from the side disposed with said signal terminal portion; and
a grounding terminal portion disposed along a side different from the side disposed with said signal terminal portion.
